(19) United States
(12) Patent Application Publication
(10) Pub. No.: US 2022/0336778 A1
(43) Pub. Date: Oct. 20, 2022

(54) ORGANIC LIGHT EMITTING DIODE DISPLAY DEVICE AND MANUFACTURING METHOD THEREOF

(71) Applicant: DB HiTek Co., Ltd., Bucheon-si (KR)

(72) Inventor: Young Jin KIM, Seoul (KR)

(21) Appl. No.: 17/720,158

(22) Filed: Apr. 13, 2022

(30) Foreign Application Priority Data
Apr. 16, 2021 (KR) 10-2021-0049525

(51) Int. Cl. H01L 51/52; H01L 51/56; H01L 27/32

(52) U.S. Cl. CPC H01L 51/5271; H01L 51/56; H01L 27/3244

(57) ABSTRACT

Disclosed is an organic light-emitting diode display device. More particularly, an organic light-emitting diode display device including a multilayer dielectric film between a reflective metal and an anode is disclosed. The multilayer film includes alternating layers of dielectric materials having different refractive indices, thereby improving reflectivity, while preventing damage to the reflective metal in subsequent processing.

### CROSS REFERENCE TO RELATED APPLICATION(S)

The present application claims priority to Korean Patent Application No. 10-2021-0049525, filed Apr. 16, 2021, the entire contents of which are incorporated herein for all purposes by this reference.

### BACKGROUND OF THE INVENTION

### 1. Technical Field

The present disclosure relates generally to an organic light-emitting diode display device and a manufacturing method thereof. More particularly, the present disclosure relates to an organic light-emitting diode display device and a manufacturing method thereof, including a multilayer dielectric film between a reflective metal and an anode that comprises a plurality of dielectric materials having different refractive indices, thereby improving reflectivity, while preventing damage to the reflective metal in subsequent processing.

### 2. Description of the Related Art

As society has entered the Information Age, the field of display devices that represent electrical signals as visual images has grown rapidly. Thus, a variety of flat display devices, exhibiting excellent performance in view of thinness, light weight, and low power consumption, have been developed. Specific examples of flat panel display devices may include a liquid crystal display (LCD) device, a plasma display panel (PDP) device, a field emission display (FED) device, an organic light-emitting diode (OLED) display device, etc.

In particular, the organic light-emitting diode display device is a self-emissive device. Compared to other flat panel display devices, the organic light-emitting diode display device has the advantages of a fast response time, a high luminous efficiency, a high luminance, and a wide viewing angle. Also, the organic light-emitting diode display device can be implemented with a high resolution and a wide screen and thus is attracting attention as a next-generation display device. An organic light-emitting diode display device has a structure in which an organic emitting layer is formed between two electrodes (an anode and a cathode).

In organic light-emitting diode display devices, electrons and holes are injected into the organic emitting layer from the two opposite electrodes, respectively, and they recombine to form an exciton. The exciton transitions from an excited state to a ground state, leading to emission of light.

FIG. 1 is a partial cross-sectional view illustrating a part of a conventional organic light-emitting diode display device 9, where an anode is formed.

Referring to FIG. 1, in the structure of the conventional organic light-emitting diode display device 9, an anode 950 comprising a metal covers only the upper surface of a dielectric layer 930, and the dielectric layer 930 covers only the upper surface of a reflective metal 910. Therefore, lateral sides of the reflective metal 910 under the dielectric layer 930 are inevitably exposed during a subsequent patterning and etching process. Here, when a subsequent ashing process or heat treatment process is performed (e.g., after the patterning and etching process) with the lateral sides of the reflective metal 910 exposed, the reflective metal 910 may be damaged because it is made of or comprises silver and/or aluminum, each of which has a relatively low melting point. Such damage may cause a decrease in reflectivity of the reflective metal 910 and may result in a leakage path between adjacent pixel regions R, G, and B.

In order to prevent such problems, a novel organic light-emitting diode display device and a manufacturing method thereof that improve reflectivity while preventing defects in a reflective metal layer during manufacturing are disclosed.

The foregoing is intended merely to aid in the understanding of the background of the present disclosure, and is not intended to mean that the present disclosure falls within the purview of the related art or that it may already be known to those skilled in the art.

### DOCUMENTS OF RELATED ART

Korean Patent Application Publication No. 10-2015-0038982 “Organic Light Emitting Display Device”

### SUMMARY OF THE INVENTION

Accordingly, the present disclosure has been made keeping in mind the above problems occurring in the related art, and an objective of the present disclosure is to provide an organic light-emitting diode display device and a manufacturing method thereof, including a reflective metal made of or comprising silver or aluminum, and in order to prevent the reflective metal from being damaged in an exposed state during subsequent etching and heat treatment processes, a metal layer for a subsequently-formed anode (hereinafter, an “anode metal”) covers the entire exposed surface of the reflective metal, thereby preventing a decrease in reflectivity and luminous efficiency.

Another objective of the present disclosure is to provide an organic light-emitting diode display device and a manufacturing method thereof that block a lateral leakage current path between adjacent pixel regions by preventing defects in the reflective metal, thereby increasing the current applied to the organic light-emitting diode display device and thus increasing the overall efficiency.

Another objective of the present disclosure is to provide an organic light-emitting diode display device and a manufacturing method thereof, in which the anode includes an extended portion connected to another extended portion on an upper insulating film, thereby preventing external exposure of the reflective metal as much as possible.

Another objective of the present disclosure is to provide an organic light-emitting diode display device and a manufacturing method thereof, in which patterning to form a horizontal extended portion of the anode simultaneously forms a trench or hole in an upper insulating film, thereby eliminating the need for a separate process (e.g., to form the horizontal extended portion of the anode), and thus facilitating the manufacturing process.

Another objective of the present disclosure is to provide an organic light-emitting diode display device and a manufacturing method thereof including a multilayer dielectric film on a reflective metal, in which the dielectric layers have different refractive indices, thereby improving reflectivity.

In order to achieve the above objectives, the present disclosure may be implemented by one or more of the following exemplary embodiments.

According to one or more embodiments of the present disclosure, there is provided an organic light-emitting diode display device including a substrate; a lower insulating film on the substrate; a lower metal layer on the lower insulating film; an upper insulating film on the lower insulating film and surrounding the lower metal layer; and a lower electrode structure on the upper insulating film. Here, the lower electrode structure may include a reflective metal on the upper insulating film; and a multilayer dielectric film (e.g., a plurality of dielectric layers) on the reflective metal.

According to one or more other embodiments of the present disclosure, the lower electrode structure may further include an anode on the multilayer film. Here, the anode may cover lateral walls of the reflective metal.

According to one or more other embodiments of the present disclosure, the multilayer dielectric film may not include successive layers of dielectric materials having the same refractive index (i.e., it may comprise layers of dielectric materials not having the same refractive index).

According to one or more other embodiments of the present disclosure, the multilayer dielectric film may comprise alternating layers of dielectric materials having different refractive indices.

According to one or more other embodiments of the present disclosure, the anode may include a first extended portion on or over an upper surface of the reflective metal; a second extended portion covering each lateral side of the reflective metal; and a third extended portion on the upper insulating film and connected to the second extended portion.

According to one or more other embodiments of the present disclosure, there is provided an organic light-emitting diode display device including a lower insulating film; a lower metal layer on the lower insulating film; an upper insulating film on the lower insulating film and surrounding the lower metal layer; and a lower electrode structure on the upper insulating film and electrically connected to the lower metal layer. Here, the lower electrode structure may include a reflective metal on the upper insulating film; a multilayer dielectric film on the reflective metal; and an anode on the multilayer film. The multilayer film may comprise alternating dielectric layers having a relatively low refractive index and a relatively high refractive index, and the anode may include a portion covering a lateral wall of the reflective metal.

According to one or more other embodiments of the present disclosure, the organic light-emitting diode display device may further include a contact region in the upper insulating film and connected to the lower metal layer and the lower electrode structure.

According to one or more other embodiments of the present disclosure, the organic light-emitting diode display device may further include an organic light-emitting layer on the lower electrode structure and the upper insulating film; a cathode on the organic light-emitting layer; and a color filter layer on the cathode.

According to one or more other embodiments of the present disclosure, the upper insulating film may include a trench or hole at a boundary between adjacent pixel regions.

According to one or more other embodiments of the present disclosure, the anode may include a first extended portion on the multilayer film; a second extended portion connected to each lateral end or edge of the first extended portion and covering the multilayer film and the reflective metal; and a third extended portion connected to the second extended portion and extending to an adjacent trench or hole.

According to one or more other embodiments of the present disclosure, the lower electrode structure may further include a buffer metal between the upper insulating film and the reflective metal.

According to one or more other embodiments of the present disclosure, the multilayer dielectric film may comprise alternating silicon nitride and tetraethyl orthosilicate (TEOS) films.

According to one or more other embodiments of the present disclosure, there is provided a method of manufacturing an organic light-emitting diode display device, the method including forming a lower insulating film on a substrate; forming a lower metal layer on the lower insulating film; forming an upper insulating film on the lower metal layer and the lower insulating film; and forming a lower electrode structure on the upper insulating film. Here, forming the lower electrode structure may include forming a reflective metal on the lower insulating film; forming a multilayer film on the reflective metal; and forming an anode that covers an upper surface of the multilayer film and lateral walls of the reflective metal.

According to one or more other embodiments of the present disclosure, forming the anode may include forming an anode metal layer on each of an upper surface of the multilayer film, lateral walls of the reflective metal and the multilayer film, and an exposed side of the upper insulating film; and etching the anode metal layer on the upper insulating film.

According to one or more other embodiments of the present disclosure, the method may further include forming a trench or hole at a boundary between adjacent pixel regions after forming the anode metal layer. Here, etching the anode metal layer and forming the trench or hole may be performed substantially simultaneously.

According to one or more other embodiments of the present disclosure, the method may further include forming an organic light-emitting layer on the anode; forming a cathode (e.g., as a common electrode) on the organic light-emitting layer; and forming a color filter layer on the cathode.

According to one or more other embodiments of the present disclosure, forming the lower electrode structure may further include forming a buffer metal on the upper insulating film before forming the reflective metal.

According to one or more other embodiments of the present disclosure, there is provided a method of manufacturing an organic light-emitting diode display device, the method including forming a lower metal layer on a lower insulating film; forming an upper insulating film on the lower metal layer and the lower insulating film; and forming a lower electrode structure on the upper insulating film. Here, forming the lower electrode structure may include forming a reflective metal on the lower insulating film; repeatedly and alternately depositing a first dielectric layer having a relatively low refractive index and a second dielectric layer having a relatively high refractive index on the reflective metal; etching the first and second dielectric layers; and forming an anode surrounding exposed sides of a multilayer film (i.e., the alternating first and second dielectric layers) and the reflective metal.

According to one or more other embodiments of the present disclosure, the first and second dielectric layers may comprise a silicon nitride film and a silicon oxide (e.g., from tetraethyl orthosilicate [TEOS]) film.

The present disclosure has the following effects by the above configurations.

After formation of a reflective metal made of or comprising silver or aluminum, in order to prevent the reflective metal from being damaged when exposed during subsequent etching and heat treatment processes, the anode covers the entire exposed surface of the reflective metal. Therefore, a decrease in reflectivity and luminous efficiency may be prevented.

Furthermore, a lateral leakage current path between adjacent pixel regions is blocked by preventing defects in the reflective metal. Therefore, the current applied to the organic light-emitting diode display device and the overall efficiency may be increased.

Furthermore, the anode includes an extended portion connected to another extended portion on an upper insulating film that completely cover the reflective metal. Therefore, there is an effect of preventing external exposure of the reflective metal as much as possible.

Furthermore, during patterning to form the third extended portion of the anode, a trench or hole can be simultaneously formed in an upper insulating film. Therefore, the need for a separate process to form the third extended portion may be eliminated, and thus facilitating the manufacturing process.

Furthermore, a multilayer dielectric film is formed on the reflective metal by depositing dielectric layers having different refractive indices. Therefore, the reflectivity of the device may be improved.

Meanwhile, the effects of the present disclosure are not limited to the above-mentioned effects, and other effects not mentioned above can be clearly understood from the following description by a person of ordinary skill in the art.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a partial cross-sectional view illustrating a part of a conventional organic light-emitting diode display device where an anode is formed;

FIG. 2 is a cross-sectional view illustrating an organic light-emitting diode display device according to one or more embodiments of the present disclosure; and

FIGS. 3 to 9 are cross-sectional views illustrating a method of manufacturing an organic light-emitting diode display device according to one or more embodiments of the present disclosure.

### DETAILED DESCRIPTION OF THE INVENTION

Reference will now be made in detail to exemplary embodiments of the disclosure, examples of which are illustrated in the accompanying drawings. The embodiments of the present disclosure can be modified in various forms. Therefore, the scope of the disclosure should not be construed as being limited to the following embodiments, but should be construed on the basis of the appended claims. Additionally, the embodiments of the present disclosure described hereinbelow are merely representative for purposes of allowing those skilled in the art to more clearly comprehend the present disclosure.

As used herein, the singular forms are intended to include the plural forms as well, unless the context clearly indicates otherwise. It will be further understood that the terms “comprise” and/or “comprising,” etc. when used in this specification, specify the presence of stated features, integers, steps, operations, elements, components, and/or combinations thereof but do not preclude the presence or addition of one or more other features, integers, steps, operations, elements, components, and/or combinations thereof.

As used herein, when an element (or layer) is referred to as being on another element (or layer), it can be directly on the other element or layer, or one or more intervening element(s) (or layer(s)) may be therebetween. In contrast, when an element is referred to as being directly on or above another component, there are no intervening element(s) therebetween. Note that the terms “on,” “above,” “below,” “upper,” “lower,” etc. are intended to describe one element's relationship to another element(s) as illustrated in the figures, rather than an absolute position in space.

When a certain embodiment may be implemented differently, a specific process order may be performed differently from the described order. For example, two consecutively described processes may be performed substantially at the same time or performed in an order opposite to the described order.

FIG. 2 is a cross-sectional view illustrating an organic light-emitting diode display device 1 according to one or more embodiments of the present disclosure.

Hereinafter, the organic light-emitting diode display device 1 will be described in detail with reference to the accompanying drawings.

Referring to FIG. 2, the organic light-emitting diode display device 1 according to the present disclosure includes a multilayer dielectric film between a reflective metal and an anode, including layers of dielectric materials having different refractive indices, thereby improving reflectivity, while preventing damage to the reflective metal in subsequent processing.

The organic light-emitting diode display device 1 may be an organic light-emitting diode on silicon (OLEDoS), which may comprise an organic light-emitting diode on a silicon wafer substrate, but there are no limitations thereto. The OLEDoS may have a structure in which organic light-emitting diodes and one or more electrodes may be formed by, for example, a CMOS process.

A description will be given of the structure of the organic light-emitting diode display device 1. A substrate 101 may have a driving element (not shown, or not identified) thereon. For example, a source (which may comprise a metal or other electrical conductor), a drain (which may also comprise a metal or other electrical conductor), etc., may be on or in the substrate 101. In addition, a lower insulating film 110 may be on the substrate 101. The lower insulating film 110 insulates the source, the drain, etc., from the structures thereabove, and may be or comprise, for example, a silicon oxide (e.g., doped or undoped silicon dioxide) film, a silicon nitride film, or a multilayer film thereof, but there are no limitations thereto.

A lower metal layer 130 may be on the lower insulating film 110, and an upper insulating film 120 may be on the lower metal layer 130 and the lower insulating film 110. The upper insulating film 120 may also comprise, for example, a silicon oxide (e.g., doped or undoped silicon dioxide) film, a silicon nitride film, or a multilayer film thereof. In addition, for example, one lower metal layer structure 130 (e.g., an interconnect) may be on or over the lower insulating film 110 in each of the pixel regions R, G, and B.

A contact hole 121 may be in the upper insulating film 120 for a contact 140 therein. The contact 140 is in contact with and thus is connected between the lower metal layer 130 and a lower electrode structure 150. The contact hole 121 exposes an upper portion (e.g., an uppermost surface) of the lower metal layer 130 and vertically passes through the upper insulating film 120. As illustrated, a pair of contact holes 121 may be spaced apart from each other in each of the pixel regions R, G, and B, but there are no limitations thereto. The lower metal layer 130 and the contact 140 may be made of or comprise a conductive metal material. In addition, a trench or hole 123 is preferably in the upper insulating film 120 at the boundary between each of the pixel regions R, G, and B to prevent leakage current between adjacent pixels. In other words, the trench or hole 123 is for the purpose of isolation between adjacent pixel regions.

The lower electrode structure 150 may be on the upper insulating film 120 in each of the pixel regions R, G, and B. The lower electrode structure 150 may comprise a buffer metal 151, a reflective metal 153, a multilayer film 155, and an anode 157, sequentially stacked from the lower side to the upper side.

The buffer metal 151 is on the upper insulating film 120 and under the reflective metal 153, and may be made of or comprise titanium nitride (TiN) or a multilayer structure of titanium nitride (TiN) and titanium (Ti), but it should be noted that the buffer metal 151 is not an essential element of the present disclosure.

The reflective metal 153 may be made of or comprise silver (Ag) having a high reflectivity for light in red and green wavelength ranges and/or aluminum (Al) having a high reflectivity for light in a blue wavelength band, but there are no limitations thereto. In more detail, it is preferable that the reflective metal 153 made of or comprising silver (Ag) having a high reflectivity for light in the red and green wavelength ranges is in each of the red pixel region R and the green pixel region G, and the reflective metal 153 made of or comprising aluminum (Al) having a high reflectivity for light in the blue wavelength range is in the blue pixel region B.

The multilayer film 155 includes a plurality of dielectric layers. For example, the multilayer film 155 may comprise a plurality of alternating dielectric layers having different refractive indices, including a first dielectric layer having a relatively low refractive index and a second dielectric layer having a relatively high refractive index. In detail, dielectric layers having the same refractive index are not repeatedly stacked or deposited. For example, another first dielectric layer may not be deposited again on a first dielectric layer, but a second dielectric layer may be deposited on a first dielectric layer, and then another first dielectric layer may be deposited on the second dielectric layer. In other words, dielectric layers having different refractive indices may alternate in the multilayer film 155.

For example, the multilayer film 155 may comprise a silicon nitride film (SiN) or silicon oxide film (SiO₂) having a relatively low refractive index, alternating with a silicon oxide film formed from tetraethyl orthosilicate (TEOS; SiO₄C₈H₂₀) having a relatively high refractive index. The number of layers in the multilayer film 155 is not limited. The multilayer film 155 may comprise, for example, a distributed Bragg reflector (DBR), which can provide a microcavity effect. As described above, the multilayer dielectric film 155 between the reflective metal 153 and the anode 157 containing layers of dielectric materials having different refractive indices may improve reflectivity. For example, the multilayer film 155 may comprise two alternating materials having different refractive indices, and may have a thickness that is ¼ (25%) of the oscillation wavelength.

The anode 157 is on the multilayer film 155 in each of the pixel regions R, G, and B. Each transistor on the substrate 101 supplies a predetermined voltage to the anode 157 in accordance with the voltage on a corresponding data line when a gate (e.g., in the pixel) receives an active signal from a corresponding gate line.

Hereinafter, a description will be given of the structure and problems of a conventional organic light-emitting diode display device 9.

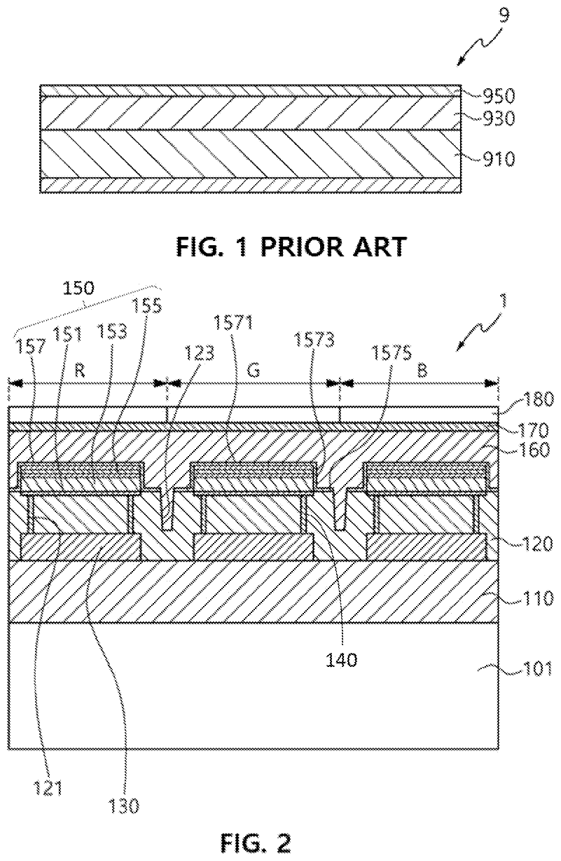

Referring to FIG. 1, in the structure of the conventional organic light-emitting diode display device 9, an anode 950 covers only an upper surface of the dielectric layer 930, which in turn covers only an upper surface of the reflective metal 910. Therefore, lateral sides of a reflective metal 910 under the dielectric layer 930 are inevitably exposed during subsequent processing. When the subsequent processing includes an ashing process or a heat treatment process performed when the lateral sides of the reflective metal 910 are exposed, and the reflective metal 910 comprises silver and/or aluminum or otherwise has a low melting point, it may be damaged. Such damage may cause a decrease in reflectivity of the reflective metal 910 and may result in a leakage path between adjacent pixel regions R, G, and B.

In order to solve the above problem, the anode 157 of the organic light-emitting diode display device 1 may extend downwards a predetermined distance to cover lateral sides of the reflective metal 153. For example, the anode 157 may include a first extended portion 1571 covering an upper surface of the multilayer film 155 and a second extended portion 1573 covering each lateral side of the reflective metal 153 (as well as the lateral sides of the multilayer film 155). The second extended portions 1573 may be connected to respective lateral ends or edges of the first extended portion 1571, but there are no limitations thereto.

The anode 157 may further include one or more third extended portions 1575 extending from the second extended portion(s) 1571 to the trench or hole 123 in the upper insulating film 120. The third extended portion 1575 does not require a separate process for its formation, but it should be noted that the third extended portion 1575 is not an essential element of the present disclosure. In addition, the formation of the third extended portion 1575 ensures that the lateral side of the reflective metal 153 is more reliably covered.

An organic light-emitting layer 160 is on the upper insulating film 120 and the lower electrode structure 150. The organic light-emitting layer 160 may include a hole transport layer (HTL), a hole injection layer (HIL), an emitting layer (EML), an electron transport layer (electron transporting layer (ETL), and an electron injection layer (EIL). When a voltage is applied to the anode 157 and a cathode 170 (which will be described later), holes and electrons move toward the organic light-emitting layer 160 and recombine to emit light. The organic light-emitting layer 160 may be a common layer that is shared by the pixel regions R, G, and B.

The cathode 170 may be on the organic light-emitting layer 160. A color filter layer 180 may be on the cathode 170. The cathode 170 may be a common layer that is shared by the pixel regions R, G, and B.

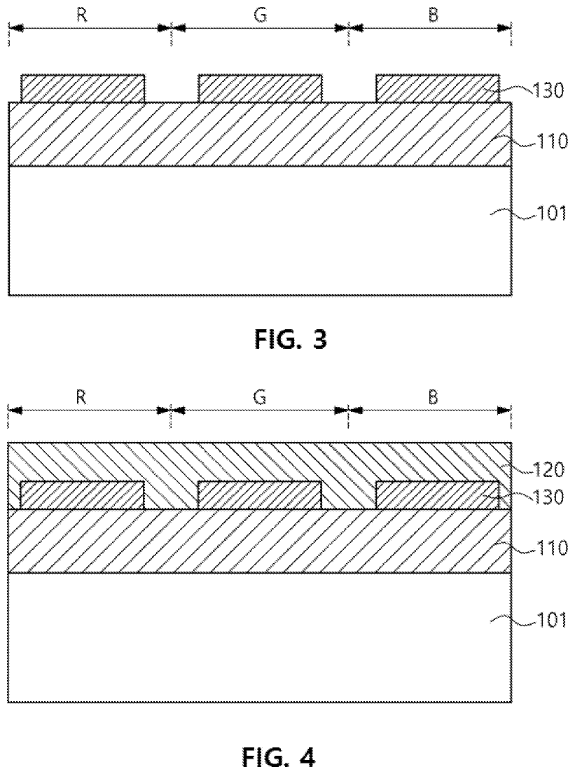

FIGS. 3 to 9 are cross-sectional views illustrating a method of manufacturing an organic light-emitting diode display device 1 according to one or more embodiments.

Hereinafter, the method of manufacturing the organic light-emitting diode display device 1 according to the present disclosure will be described in detail with reference to the accompanying drawings.

First, referring to FIG. 3, a lower insulating film 110 is deposited on a substrate 101. Thereafter, a lower metal layer 130 is formed on the lower insulating film 110. To form the lower metal layer 130, for example, the metal layer (not illustrated) may be blanket-deposited on the lower insulating film 110, after which a mask pattern having openings in the areas where the metal layer will be removed may be formed on the metal layer, and then the exposed metal layer is etched to form the lower metal layer 130 in each pixel region.

Thereafter, referring to FIG. 4, an upper insulating film 120 may be deposited on the lower insulating film 110 and the lower metal layer 130. The upper insulating film 120 may be or comprise an inorganic insulating film, for example, a silicon oxide film (as described herein), a silicon nitride film, or a multilayer film thereof. The uppermost surface of the upper insulating film 120 may be planarized (i.e., made flat) by conventional chemical mechanical polishing (CMP).

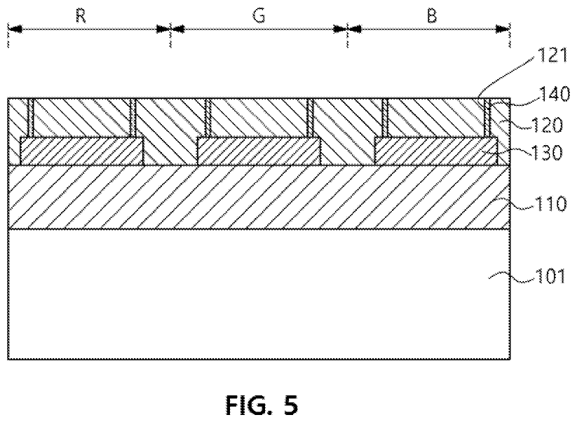

Thereafter, referring to FIG. 5, contacts 140 are formed in the upper insulating film 120. In detail, a mask pattern having openings in the locations where contact holes 121 will be formed is formed on the upper insulating film 120, and then the exposed areas of the upper insulating film 120 are etched to form the contact holes 121 (e.g., in each pixel region). Then, one or more layers of metal and/or other conductive material (not illustrated) are blanket-deposited in the contact holes 121 and on the upper insulating film 120 to fill the contact holes 121, and a CMP process is performed to remove the layer(s) of metal or other conductive material and expose an upper surface of the upper insulating film 120. The contacts 140 are preferably made of or comprise, for example, a metal such as copper, aluminum, titanium or tungsten, and optionally, a conductive material such as titanium nitride (TiN). More preferably, the contacts 140 comprise tungsten.

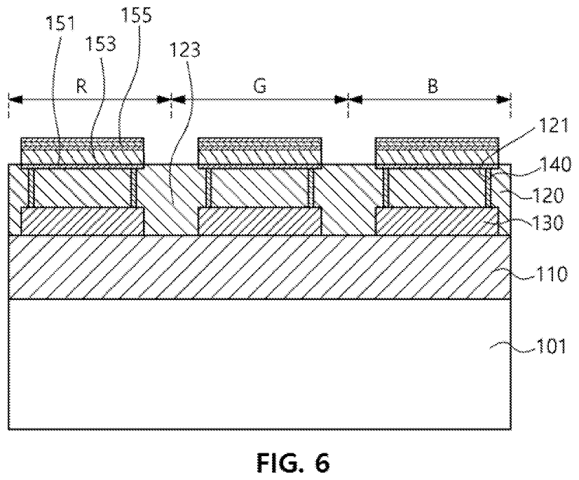

After the formation of the contacts 140, referring to FIG. 6, a lower electrode structure 150 is formed on the upper insulating film 120 (e.g., in each pixel region). First, a material layer for forming the buffer metal 151 is blanket-deposited on the upper insulating film 120, a material layer for forming the reflective metal 153 is blanket-deposited on the buffer metal 151, and layers of dielectric materials for forming the multilayer film 155 are blanket-deposited on the reflective metal 153. Thereafter, a mask pattern (not illustrated) may be formed on the multilayer film 155, and then the exposed areas of the dielectric material layers, the reflective metal material layer, and buffer material layer are etched to form the buffer metal 151, the reflective metal 153, and the multilayer film 155, respectively, in each pixel region. Alternatively, the material layers for forming the buffer metal 151 and the reflective metal 153 may be deposited and etched, and then the material layers for forming the multilayer film 155 may be deposited and etched, but there are no limitations thereto.

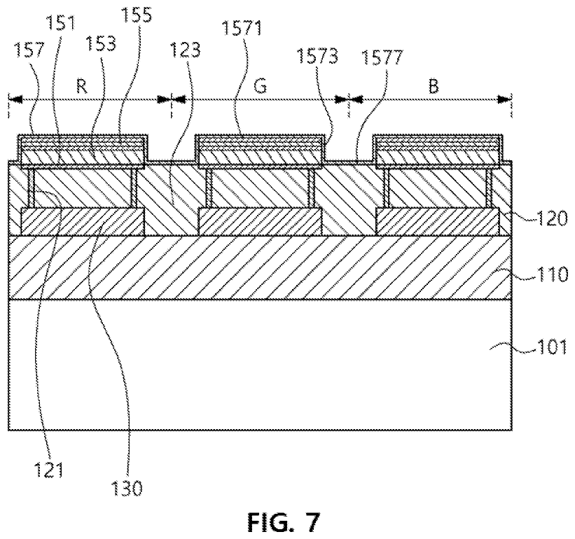

Thereafter, referring to FIG. 7, an anode metal 1571, 1573 and 1577 is formed on the multilayer film 155. As described above, the anode metal 1571, 1573 and 1577 may cover lateral walls of the reflective metal 153, the multilayer film 155, and optionally, the buffer metal 151. For example, a metal layer may be conformally deposited on exposed areas of the upper insulating film 120, the multilayer film 155, and lateral walls of the multilayer film 155, the reflective metal 153, and optionally, the buffer metal 151. In other words, the anode metal may comprise a first extended portion 1571, a second extended portion 1573, and a preliminary third extended portion 1577, the latter of which may be on the upper insulating film 120. The formation of the second extended portion 1573 ensures that the entire surface of the reflective metal 153 is covered (i.e., not exposed) during subsequent processing, thereby protecting the reflective metal 153 during subsequent etching and/or heat treatment processes. Therefore, it is possible to prevent occurrence of defects or loss caused by corrosion of or precipitation of/in the reflective metal 153.

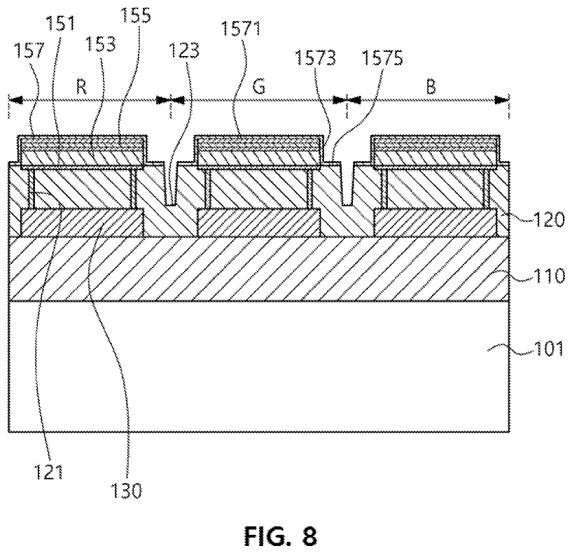

Thereafter, referring to FIG. 8, photolithographic patterning and etching processes are performed to form the trenches or holes 123 in the upper insulating film 120. The anode metal 1571. 1573 and 1577 is etched in the locations where the trenches or holes 123 are formed. In detail, a mask pattern having openings in the areas where the trenches or holes 123 will be formed is formed on the upper insulating film 120, and then the exposed areas of the upper insulating film 120 are etched to form the trenches or holes 123 at the boundaries between adjacent pixel regions. As a result, the preliminary third extended portion 1577 is partially etched to separate it into third extended portions 1575. As described above, since the third extended portions 1575 and the trenches or holes 123 are formed simultaneously, this is advantageous in that exposure of the reflective metal 153 can be prevented as much as possible, and a separate process is not required.

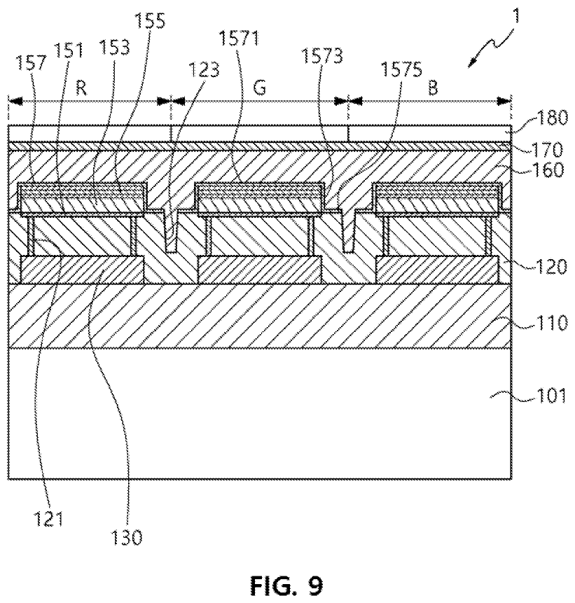

Thereafter, referring to FIG. 9, an organic light-emitting layer 160 is formed on the anode 157 (and thus also on the lower electrode structures 150 and the upper insulating film 120) and in the trenches or holes 123, after which a cathode 170 is formed (e.g., by blanket deposition) on the organic light-emitting layer 160. Before blanket deposition of the cathode 170, the organic light-emitting layer 160 may be conventionally planarized. Thereafter, a color filter layer 180 is formed on the cathode 170.

The foregoing detailed description merely sets forth examples of the disclosure. Also, the above contents explain various embodiments of the present disclosure, and the present disclosure may allow various combinations, modifications, and environments. In other words, the present disclosure may be changed or modified within the scope of the disclosure herein, the disclosed contents, their equivalents and/or the techniques and knowledge in the art. The foregoing embodiments are for illustrating the best mode and/or for implementing the technical ideas of the present disclosure, and various modifications may be made therein according to specific applications and/or uses of the present disclosure. Therefore, it is intended that the scope of the present disclosure be defined by the appended claims and their equivalents.

What is claimed is:

1. An organic light-emitting diode display device comprising:
a substrate;
a lower insulating film on the substrate;
a lower metal layer on the lower insulating film;
an upper insulating film on the lower insulating film and surrounding the lower metal layer; and
a lower electrode structure on the upper insulating film,
wherein the lower electrode structure comprises:
a reflective metal on the upper insulating film; and
a multilayer dielectric film on the reflective metal.

2. The organic light-emitting diode display device of claim 1, wherein the lower electrode structure further comprises an anode on the multilayer film,
wherein the anode covers lateral walls of the reflective metal.

3. The organic light-emitting diode display device of claim 2, wherein the multilayer dielectric film comprises layers of dielectric materials not having a same refractive index.

4. The organic light-emitting diode display device of claim 2, wherein the multilayer dielectric film comprises alternating layers of dielectric materials having different refractive indices.

5. The organic light-emitting diode display device of claim 4, wherein the anode comprises:
a first extended portion on or over an upper surface of the reflective metal;
a second extended portion covering each lateral side of the reflective metal; and
a third extended portion on the upper insulating film and connected to the second extended portion.

6. An organic light-emitting diode display device comprising:
a lower insulating film;
a lower metal layer on the lower insulating film;
an upper insulating film on the lower insulating film and surrounding the lower metal layer; and
a lower electrode structure on the upper insulating film and electrically connected to the lower metal layer,
wherein the lower electrode structure comprises:
a reflective metal on the upper insulating film;
a multilayer film comprising a plurality of dielectric layers on the reflective metal; and
an anode on the multilayer film,
the multilayer film comprises alternating dielectric layers having a relatively low refractive index and a relatively high refractive index, and
the anode comprises a portion covering a lateral wall of the reflective metal.

7. The organic light-emitting diode display device of claim 6, further comprising a contact region in the upper insulating film and connected to the lower metal layer and the lower electrode structure.

8. The organic light-emitting diode display device of claim 7, further comprising:
an organic light-emitting layer on the lower electrode structure and the upper insulating film;
a cathode on the organic light-emitting layer; and
a color filter layer on the cathode.

9. The organic light-emitting diode display device of claim 7, wherein the upper insulating film comprises a trench or hole at a boundary between adjacent pixel regions.

10. The organic light-emitting diode display device of claim 7, wherein the anode comprises:
a first extended portion on the multilayer film;
a second extended portion connected to each lateral end or edge of the first extended portion and covering the multilayer film and the reflective metal; and
a third extended portion connected to the second extended portion and extending to an adjacent trench or hole.

11. The organic light-emitting diode display device of claim 10, wherein the lower electrode structure further comprises a buffer metal between the upper insulating film and the reflective metal.

12. The organic light-emitting diode display device of claim 10, wherein the multilayer film comprises alternating silicon nitride and tetraethyl orthosilicate (TEOS) films.

13. A method of manufacturing an organic light-emitting diode display device, the method comprising:
forming a lower insulating film on a substrate;
forming a lower metal layer on the lower insulating film;
forming an upper insulating film on the lower metal layer and the lower insulating film; and
forming a lower electrode structure on the upper insulating film,
wherein forming the lower electrode structure comprises:
forming a reflective metal on the lower insulating film;
forming a multilayer film on the reflective metal; and
forming an anode that covers an upper surface of the multilayer film and lateral walls of the reflective metal.

14. The method of claim 13, wherein forming the anode comprises:
forming an anode metal layer on each of an upper surface of the multilayer film, lateral walls of the reflective metal and the multilayer film, and an exposed side of the upper insulating film; and
etching the anode metal layer on the upper insulating film.

15. The method of claim 14, further comprising forming a trench or hole at a boundary between adjacent pixel regions after forming the anode metal layer,
wherein etching the anode metal layer and forming the trench or hole are performed substantially simultaneously.

16. The method of claim 14, further comprising:
forming an organic light-emitting layer on the anode;
forming a cathode on the organic light-emitting layer; and
forming a color filter layer on the cathode.

17. The method of claim 14, wherein forming the lower electrode structure further comprises forming a buffer metal on the upper insulating film before forming the reflective metal.

18. A method of manufacturing an organic light-emitting diode display device, the method comprising:
forming a lower metal layer on a lower insulating film;
forming an upper insulating film on the lower metal layer and the lower insulating film; and
forming a lower electrode structure on the upper insulating film,
wherein forming the lower electrode structure comprises:
forming a reflective metal on the lower insulating film;
repeatedly and alternately depositing a first dielectric layer having a relatively low refractive index and a second dielectric layer having a relatively high refractive index on the reflective metal;
etching the first and second dielectric layers; and
forming an anode surrounding exposed sides of the first and second dielectric layers and the reflective metal.

19. The method of claim 18, wherein the first and second dielectric layers comprise a silicon nitride film and a tetraethyl orthosilicate (TEOS) film.
